(19) United States
(12) Patent Application Publication
(10) Pub. No.: US 2018/0217204 A1
(43) Pub. Date: Aug. 2, 2018

(54) Counter-Based Scan Chain Diagnosis

(71) Applicant: Mentor Graphics Corporation, Wilsonville, OR (US)

(72) Inventors: Yu Huang, West Linn, OR (US); Robert Randal Klingenberg, Beaverton, OR (US); Huaxing Tang, Wilsonville, OR (US); Jayant Conrad D'Souza, Wilsonville, OR (US); Wu-Tung Cheng, Lake Oswego, OR (US)

(73) Assignee: Mentor Graphics Corporation

(21) Appl. No.: 15/420,966

(22) Filed: Jan. 31, 2017

(51) Int. Cl. G01R 31/3177; G11C 29/38; G11C 29/44; G01R 31/317

(52) U.S. Cl. CPC G01R 31/3177; G11C 29/38; G01R 31/31723; G01R 31/31703; G11C 29/44

(57) ABSTRACT

Various aspects of the present disclosed technology relate to techniques of locating defective memory cells based on scan chain diagnosis. Chain pattern responses of a circuit are first analyzed and at least one or more chain segment defect candidates on one faulty scan chain in the circuit and a fault model associated with the one faulty scan chain are determined. Here, each of the one or more chain segment defect candidates is a counter-based scan chain unit derived from a part or a whole of a memory array. Scan pattern responses are then analyzed to determine one or more memory cell defect candidates in the one or more chain segment defect candidates based on the information of the part or the whole of the memory array and the fault model.

### FIELD OF THE DISCLOSED TECHNOLOGY

The present disclosed technology relates to circuit testing. Various implementations of the disclosed technology may be particularly useful for locating defective memory cells.

### BACKGROUND OF THE DISCLOSED TECHNOLOGY

Scan-based testing has been widely used in digital circuits as a design-for-test (DFT) technique. Scan elements and related clocking circuitry take up about 30% of silicon area of an integrated circuit chip. It is estimated that 50% of chip failures are caused by scan chain defects. Diagnosing scan chain faults is thus important to guide silicon debug, physical failure analysis (PFA), and yield learning process.

Physical failure analysis instruments are sometimes used together with a tester to observe defective responses at different locations and to identify a failing scan cell. These hardware-based methods often rely on specially-designed scan chains and scan cells. While effective in isolating scan chain defects, the requirement of extra hardware may not be acceptable in many realistic products. Further, it is difficult to apply these methods to chips with embedded compression circuits without resorting bypass mode.

Software-based techniques use algorithmic diagnosis procedures to identify failing scan cells. It may run chain diagnosis with conventional scan chains with or without embedded compressions. The current software-based chain diagnosis techniques may be further classified into two categories: model-based algorithms and data-driven algorithms. In a model-based chain diagnosis process, fault models and pattern simulation are used. In a data-driven chain diagnosis process, signal profiling, filtering and edge detections are applied. Each category of algorithms has its own advantages and disadvantages. These two can also be combined to increase diagnosis resolution and accuracy.

Having been applied successfully to traditional scan chains, the conventional software-based chain diagnosis techniques cannot work with scan chains that are counter-based or include counter-based segments. Counter-based scan chains or scan chain segments are derived from memories (memory arrays). Modern circuit designs often include many memory arrays. To test memory arrays, memory BIST (built-in self-test) devices are typically inserted into circuit designs. While a memory BIST device can thoroughly test a memory array, it adds area overhead to the circuit design. This may not be desirable for shallow and high-performance memory arrays like register files used extensively in some circuit designs. Counter-based scan chain diagnosis can serve as a viable alternative for testing these memory arrays.

### BRIEF SUMMARY OF THE DISCLOSED TECHNOLOGY

Various aspects of the present disclosed technology relate to techniques of locating defective memory cells based on scan chain diagnosis. In one aspect, there is a method comprising: analyzing chain pattern responses of a circuit generated by a first process comprising shifting in chain patterns and shifting out the chain pattern responses, wherein the analyzing chain pattern responses determines at least one or more chain segment defect candidates on one faulty scan chain in the circuit and a fault model associated with the one faulty scan chain, and wherein each of the one or more chain segment defect candidates is a counter-based scan chain unit derived from a part or a whole of a memory array and the determining is based, at least in part, on information of the part or the whole of the memory array; and analyzing scan pattern responses generated by a second process comprising shifting in scan patterns, capturing the scan pattern responses, and shifting out the scan pattern responses to determine one or more memory cell defect candidates in the one or more chain segment defect candidates based on the information of the part or the whole of the memory array and the fault model.

The analyzing the scan pattern responses may comprise performing a data-driven scan chain diagnosis process, a model-based scan chain diagnosis process, or both. The scan patterns may be ATPG scan patterns.

The fault model may be a slow-rise fault, a slow-fall fault, a slow fault, a fast-rise fault, a fast-fall fault, a fast (hold time) fault, a stuck-at-1 fault, a stuck-at-0 fault, or an indeterminate fault.

The information of the part or the whole of the memory array may comprise a number of addresses of the memory array. The information of the part or the whole of the memory array may further comprise location information of each of the one or more chain segment defect candidates.

In another aspect, there are one or more non-transitory computer-readable media storing computer-executable instructions for causing one or more processors to perform the above method.

In still another aspect, there is a system, comprising: one or more processors, the one or more processors programmed to perform the above method.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclosed technology. Thus, for example, those skilled in the art will recognize that the disclosed technology may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 illustrates an example of a computing system that may be used to implement various embodiments of the disclosed technology.

FIG. 2 illustrates an example of a multi-core processor unit that may be used to implement various embodiments of the disclosed technology.

FIG. 3A illustrates an example of a memory array that can serve as a counter-based scan chain or a counter-based scan chain segment of a scan chain; FIG. 3B illustrates an example of data bit cells inside a memory array 340; FIG. 3C illustrates what happens when four data bits “dcba” are shifted in a scan chain derived from the memory array 340; FIG. 3D illustrates a sequence of all of the originally stored data bits being shifted out of the memory array 340.

FIG. 4 illustrates an example of a counter-based scan chain diagnosis tool 400 that may be implemented according to various embodiments of the disclosed technology.

FIG. 5 illustrates a flowchart 500 showing a process of defective memory cell identification based on chain diagnosis that may be implemented according to various examples of the disclosed technology.

FIG. 6 illustrates an example of a scan chain having multiple counter-based scan chain units along with conventional scan cells.

FIG. 7 illustrates an example of a chain pattern and chain pattern responses of a conventional faulty scan chain for eight fault models.

FIG. 8 illustrates an example of fault model effect differences between conventional scan chains and scan chains containing a counter-based scan chain unit.

### DETAILED DESCRIPTION OF THE DISCLOSED TECHNOLOGY

Various aspects of the present disclosed technology relate to techniques of locating defective memory cells based on scan chain diagnosis. In the following description, numerous details are set forth for purpose of explanation. However, one of ordinary skill in the art will realize that the disclosed technology may be practiced without the use of these specific details. In other instances, well-known features have not been described in detail to avoid obscuring the present disclosed technology.

Although the operations of some of the disclosed methods, apparatus, and systems are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods, apparatus, and systems can be used in conjunction with other methods, apparatus, and systems. Additionally, the description sometimes uses terms like “analyze”, “derive” and “determine” to describe the disclosed methods. These terms are high-level abstractions of the actual operations that are performed. The actual operations that correspond to these terms may vary depending on the particular implementation and are readily discernible by one of ordinary skill in the art.

Any of the disclosed techniques can be implemented in whole or in part by software comprising computer-executable instructions stored on computer-readable media. Such software can comprise, for example, an appropriate electronic design automation (“EDA”) software tool. Such software can be executed on a single computer or on a networked computer (e.g., via the Internet, a wide-area network, a local-area network, a client-server network, or other such network). For clarity, only certain selected aspects of the software-based implementations are described. Other details that are well known in the art are omitted. For example, it should be understood that the disclosed technology is not limited to any specific computer language, program, or computer. For example, the disclosed technology can be implemented using any commercially available computer executing a program written in any commercially available or otherwise suitable language. Any of the disclosed methods can alternatively be implemented (partially or completely) in hardware (e.g., an ASIC, PLD, or SoC).

Any data produced from any of the disclosed methods (e.g., intermediate or final test patterns, test patterns values, or control data) can be stored on computer-readable media (e.g., tangible computer-readable media, such as one or more CDs, volatile memory components (such as DRAM or SRAM), or nonvolatile memory components (such as hard drives)) using a variety of different data structures or formats. Such data can be created, updated, or stored using a local computer or over a network (e.g., by a server computer).

As used in this disclosure, the singular forms “a,” “an,” and “the” include the plural forms unless the context clearly dictates otherwise. Additionally, the term “includes” means “comprises.” Moreover, the term “design” is intended to encompass data describing an entire microdevice, such as an integrated circuit device or micro-electromechanical system (MEMS) device. This term also is intended to encompass a smaller group of data describing one or more components of an entire microdevice, however, such as a layer of an integrated circuit device, or even a portion of a layer of an integrated circuit device.

Still further, the term “design” also is intended to encompass data describing more than one microdevice, such as data to be used to create a mask or reticle for simultaneously forming multiple microdevices on a single wafer. The layout design data may be in any desired format, such as, for example, the Graphic Data System II (GDSII) data format or the Open Artwork System Interchange Standard (OASIS) data format proposed by Semiconductor Equipment and Materials International (SEMI). Other formats include an open source format named Open Access, Milkyway by Synopsys, Inc., and EDDM by Mentor Graphics, Inc.

### Illustrative Operating Environment

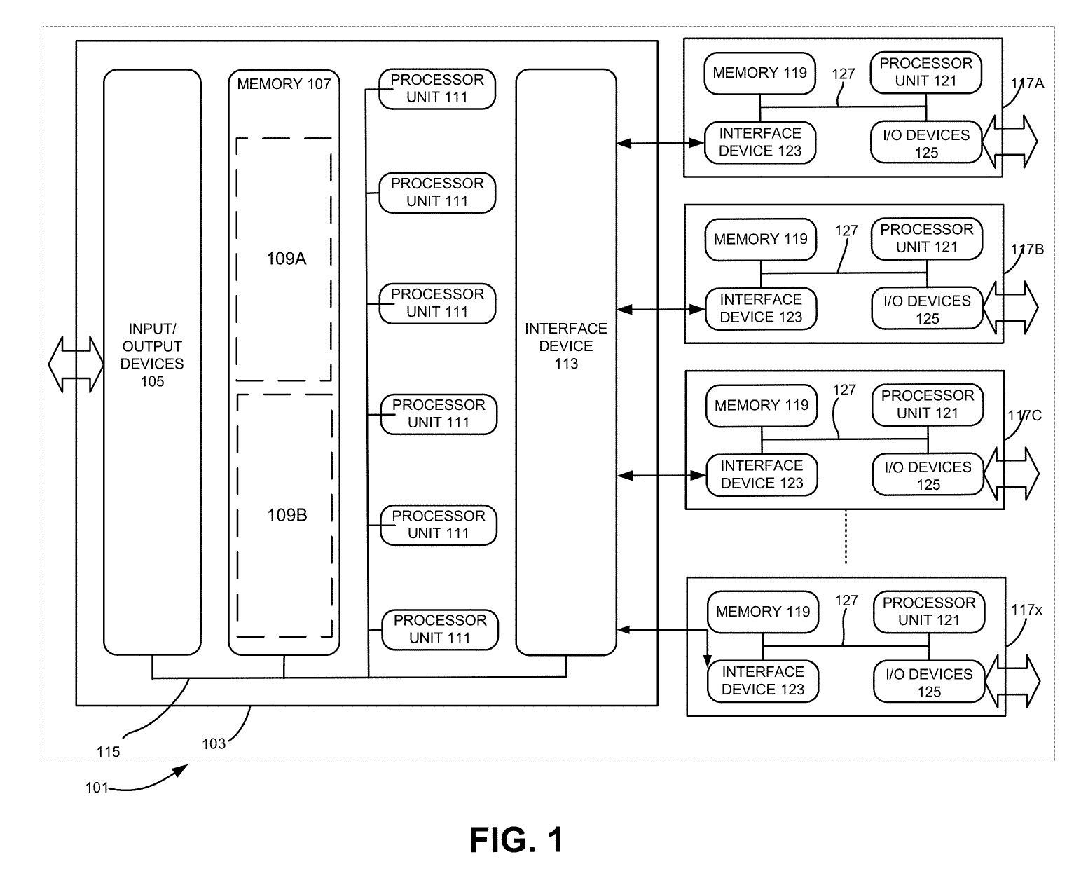

The execution of various electronic design automation processes according to embodiments of the disclosed technology may be implemented using computer-executable software instructions executed by one or more programmable computing devices. Because these embodiments of the disclosed technology may be implemented using software instructions, the components and operation of a generic programmable computer system on which various embodiments of the disclosed technology may be employed will first be described. Further, because of the complexity of some electronic design automation processes and the large size of many circuit designs, various electronic design automation tools are configured to operate on a computing system capable of simultaneously running multiple processing threads. The components and operation of a computer network having a host or master computer and one or more remote or servant computers therefore will be described with reference to FIG. 1. This operating environment is only one example of a suitable operating environment, however, and is not intended to suggest any limitation as to the scope of use or functionality of the disclosed technology.

In FIG. 1, the computer network 101 includes a master computer 103. In the illustrated example, the master computer 103 is a multi-processor computer that includes a plurality of input and output devices 105 and a memory 107. The input and output devices 105 may include any device for receiving input data from or providing output data to a user. The input devices may include, for example, a keyboard, microphone, scanner or pointing device for receiving input from a user. The output devices may then include a display monitor, speaker, printer or tactile feedback device. These devices and their connections are well known in the art, and thus will not be discussed at length here.

The memory 107 may similarly be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information.

As will be discussed in detail below, the master computer 103 runs a software application for performing one or more operations according to various examples of the disclosed technology. Accordingly, the memory 107 stores software instructions 109A that, when executed, will implement a software application for performing one or more operations. The memory 107 also stores data 109B to be used with the software application. In the illustrated embodiment, the data 109B contains process data that the software application uses to perform the operations, at least some of which may be parallel.

The master computer 103 also includes a plurality of processor units 111 and an interface device 113. The processor units 111 may be any type of processor device that can be programmed to execute the software instructions 109A, but will conventionally be a microprocessor device. For example, one or more of the processor units 111 may be a commercially generic programmable microprocessor, such as Intel® Pentium® or Xeon™ microprocessors, Advanced Micro Devices Athlon™ microprocessors or Motorola 68K/Coldfire® microprocessors. Alternately or additionally, one or more of the processor units 111 may be a custom-manufactured processor, such as a microprocessor designed to optimally perform specific types of mathematical operations. The interface device 113, the processor units 111, the memory 107 and the input/output devices 105 are connected together by a bus 115.

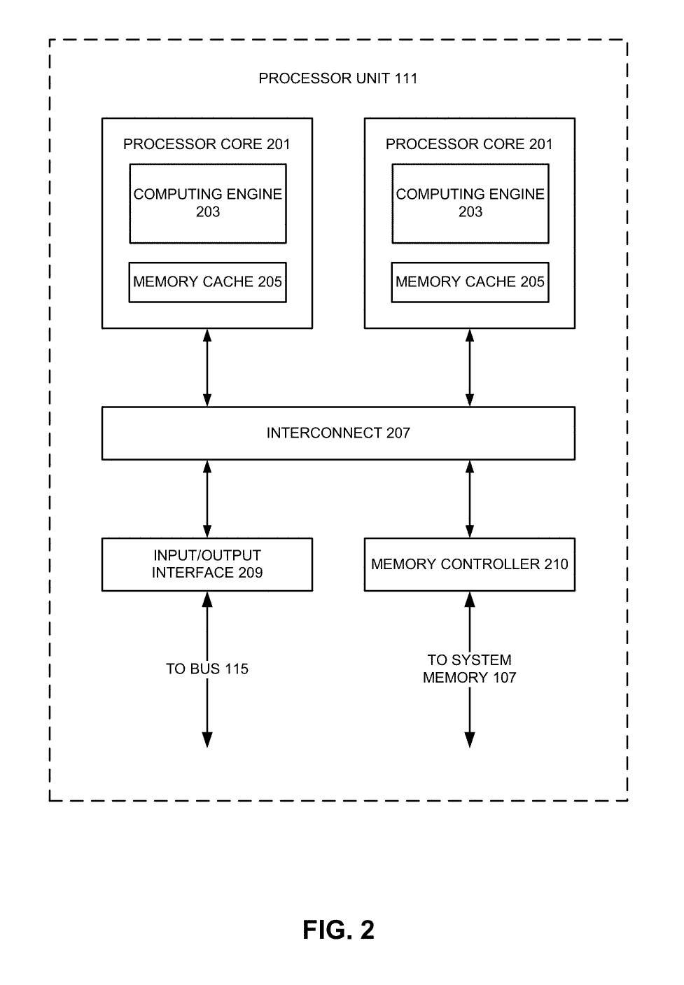

With some implementations of the disclosed technology, the master computing device 103 may employ one or more processing units 111 having more than one processor core. Accordingly, FIG. 2 illustrates an example of a multi-core processor unit 111 that may be employed with various embodiments of the disclosed technology. As seen in this figure, the processor unit 111 includes a plurality of processor cores 201. Each processor core 201 includes a computing engine 203 and a memory cache 205. As known to those of ordinary skill in the art, a computing engine contains logic devices for performing various computing functions, such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203 may then use its corresponding memory cache 205 to quickly store and retrieve data and/or instructions for execution.

Each processor core 201 is connected to an interconnect 207. The particular construction of the interconnect 207 may vary depending upon the architecture of the processor unit 111. With some processor cores 201, such as the Cell microprocessor created by Sony Corporation, Toshiba Corporation and IBM Corporation, the interconnect 207 may be implemented as an interconnect bus. With other processor units 111, however, such as the Opteron™ and Athlon™ dual-core processors available from Advanced Micro Devices of Sunnyvale, Calif., the interconnect 207 may be implemented as a system request interface device. In any case, the processor cores 201 communicate through the interconnect 207 with an input/output interface 209 and a memory controller 210. The input/output interface 209 provides a communication interface between the processor unit 111 and the bus 115. Similarly, the memory controller 210 controls the exchange of information between the processor unit 111 and the system memory 107. With some implementations of the disclosed technology, the processor units 111 may include additional components, such as a high-level cache memory accessible shared by the processor cores 201.

While FIG. 2 shows one illustration of a processor unit 111 that may be employed by some embodiments of the disclosed technology, it should be appreciated that this illustration is representative only, and is not intended to be limiting. Also, with some implementations, a multi-core processor unit 111 can be used in lieu of multiple, separate processor units 111. For example, rather than employing six separate processor units 111, an alternate implementation of the disclosed technology may employ a single processor unit 111 having six cores, two multi-core processor units each having three cores, a multi-core processor unit 111 with four cores together with two separate single-core processor units 111, etc.

Returning now to FIG. 1, the interface device 113 allows the master computer 103 to communicate with the servant computers 117A, 117B, 117C . . . 117x through a communication interface. The communication interface may be any suitable type of interface including, for example, a conventional wired network connection or an optically transmissive wired network connection. The communication interface may also be a wireless connection, such as a wireless optical connection, a radio frequency connection, an infrared connection, or even an acoustic connection. The interface device 113 translates data and control signals from the master computer 103 and each of the servant computers 117 into network messages according to one or more communication protocols, such as the transmission control protocol (TCP), the user datagram protocol (UDP), and the Internet protocol (IP). These and other conventional communication protocols are well known in the art, and thus will not be discussed here in more detail.

Each servant computer 117 may include a memory 119, a processor unit 121, an interface device 123, and, optionally, one more input/output devices 125 connected together by a system bus 127. As with the master computer 103, the optional input/output devices 125 for the servant computers 117 may include any conventional input or output devices, such as keyboards, pointing devices, microphones, display monitors, speakers, and printers. Similarly, the processor units 121 may be any type of conventional or custom-manufactured programmable processor device. For example, one or more of the processor units 121 may be commercially generic programmable microprocessors, such as Intel® Pentium® or Xeon™ microprocessors, Advanced Micro Devices Athlon™ microprocessors or Motorola 68K/Coldfire® microprocessors. Alternately, one or more of the processor units 121 may be custom-manufactured processors, such as microprocessors designed to optimally perform specific types of mathematical operations. Still further, one or more of the processor units 121 may have more than one core, as described with reference to FIG. 2 above. For example, with some implementations of the disclosed technology, one or more of the processor units 121 may be a Cell processor. The memory 119 then may be implemented using any combination of the computer readable media discussed above. Like the interface device 113, the interface devices 123 allow the servant computers 117 to communicate with the master computer 103 over the communication interface.

In the illustrated example, the master computer 103 is a multi-processor unit computer with multiple processor units 111, while each servant computer 117 has a single processor unit 121. It should be noted, however, that alternate implementations of the disclosed technology may employ a master computer having single processor unit 111. Further, one or more of the servant computers 117 may have multiple processor units 121, depending upon their intended use, as previously discussed. Also, while only a single interface device 113 or 123 is illustrated for both the master computer 103 and the servant computers, it should be noted that, with alternate embodiments of the disclosed technology, either the computer 103, one or more of the servant computers 117, or some combination of both may use two or more different interface devices 113 or 123 for communicating over multiple communication interfaces.

With various examples of the disclosed technology, the master computer 103 may be connected to one or more external data storage devices. These external data storage devices may be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information. According to some implementations of the disclosed technology, one or more of the servant computers 117 may alternately or additionally be connected to one or more external data storage devices. Typically, these external data storage devices will include data storage devices that also are connected to the master computer 103, but they also may be different from any data storage devices accessible by the master computer 103.

It also should be appreciated that the description of the computer network illustrated in FIG. 1 and FIG. 2 is provided as an example only, and it not intended to suggest any limitation as to the scope of use or functionality of alternate embodiments of the disclosed technology.

### Counter-Based Scan

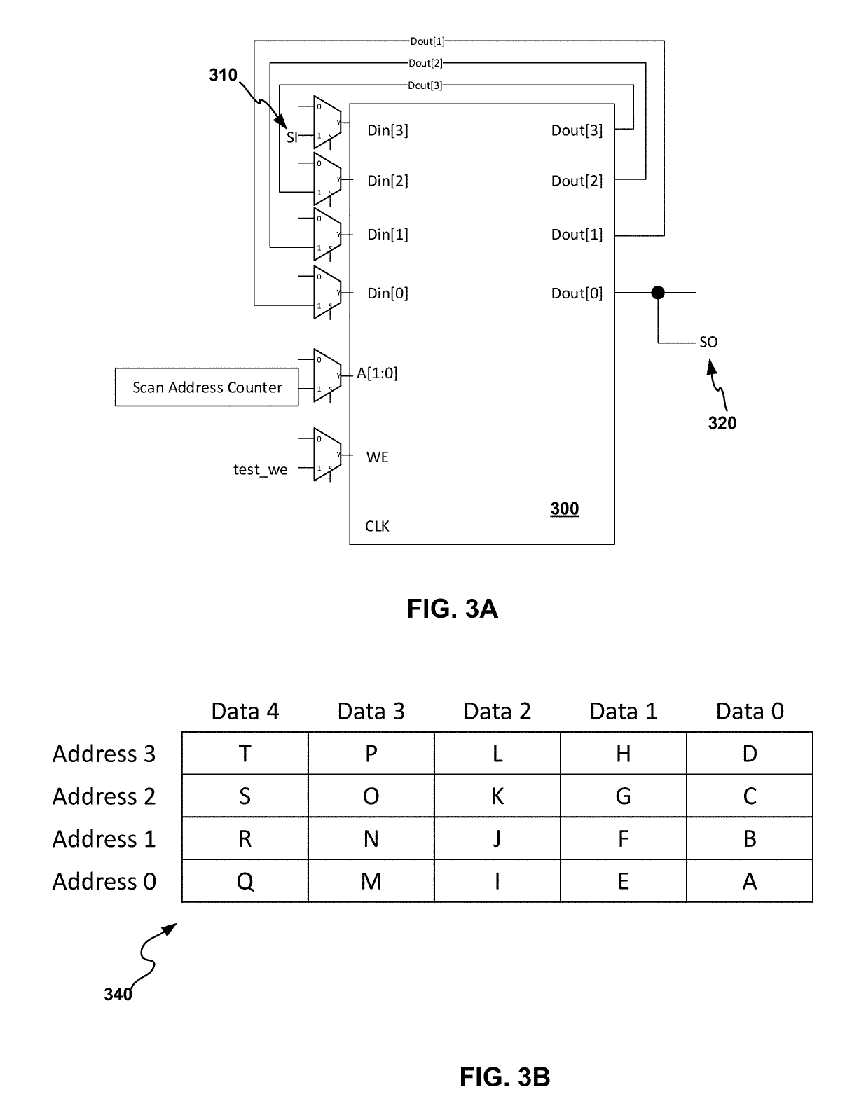

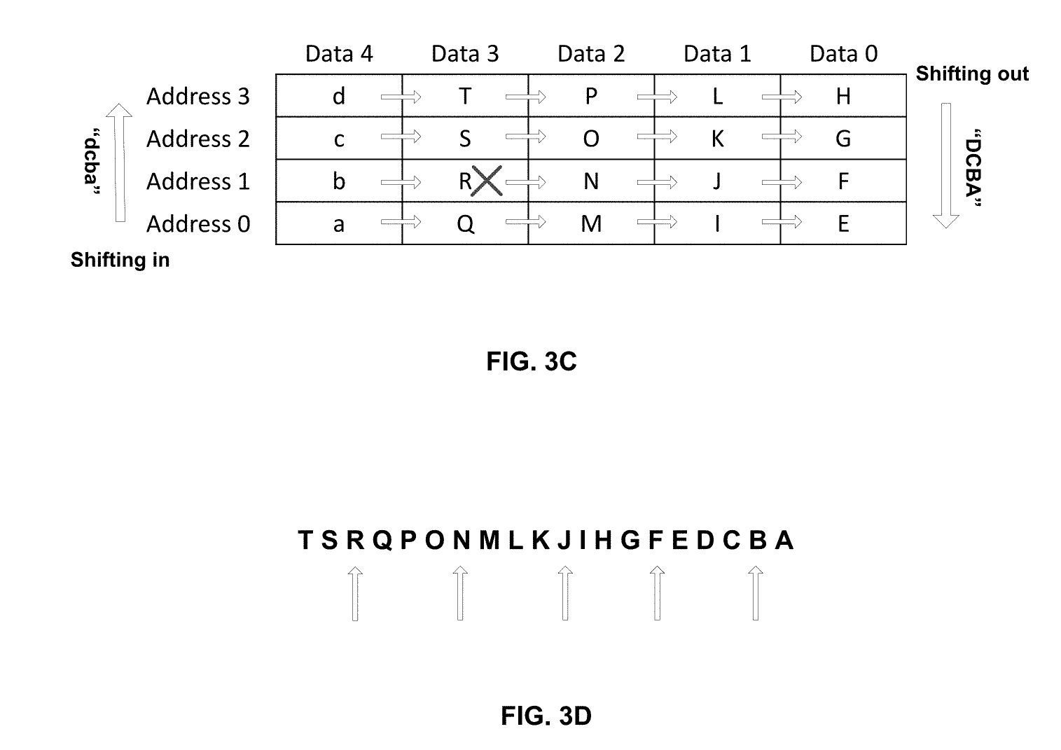

Conventional scan is one-dimensional serial scan. When reaching the last scan cell of a scan chain, a data bit has passed through all of the other scan cells of the scan chain one after another in order. Counter-based scan, by contrast, can be considered as two-dimensional scan. Counter-based scan chains or scan chain segments are usually derived from memory arrays. A scan address counter is often used to control the visit of memory bit cells in a memory array. FIG. 3A illustrates an example of a memory array that can serve as a counter-based scan chain or a counter-based scan chain segment of a scan chain. In the figure, the memory array 300 has four data bits per address. The scan input is coupled to the input of data bit cell #3 and the scan output is coupled to the output of data bit cell #0. While the four data bit cells are connected like scan cells on a regular scan chain for each address, a scan address counter 330 selects one address per shift clock cycle for both a data bit to be shifted into and a data bit to be shifted out of the memory array 300.

FIG. 3B illustrates an example of data bit cells inside a memory array. In the figure, the memory array 340 has four addresses and in each address, there are five data bit cells. The letter in each of the bit cells represents a currently stored data bit, which may be “1” or “0”. FIG. 3C illustrates what happens when four data bits “dcba” are shifted in a scan chain derived from the memory array 340. Here, the address counter starts with 0 and “a” is loaded into data bit cell #4 of address 0 at the first shift clock cycle, while the originally stored bits in the data bit cells of the same address are moved to their neighboring data bit cells with “A” being shifted out of the memory array 340.

Next, the address counter points to address 1 and “b” is loaded into data bit cell #4 of address 1, while the originally stored bits are shifted to the neighboring data bit cells with “B” being shifted out. Similarly, “c” and “d” are loaded into corresponding data bits cells and “C” and “D” are shifted out consecutively. The shifting pattern is illustrated in FIG. 3C. This explains why the counter-based scan is called “two-dimensional scan”: data bits are shifted vertically one address after another but horizontally within each address. FIG. 3D illustrates a sequence of all of the originally stored data bits being shifted out.

Assuming there is a fault associated with the data bit cell #3 of address 1, as illustrated by “X” in FIG. 3C. After being shifted in and out, only “R”, “N”, “J”, “F”, and “B” may be affected. That is, the affected data bits may happen once every five bits. If the bits are numbered consecutively, the affected bits are congruent modulo n, where n is the number of addresses used for a scan chain. This is in contrast to a conventional scan chain: every data bit may be affected after being shifted in and out if there is a fault associated with scan cell.

It should be noted that the architecture shown in FIG. 3A is just an example and any number of data bit cells may be connected for one scan chain. For instance, data bit cells #0 and #1 in FIG. 3A may be used as a segment of a scan chain and the other half may be used as a segment of another scan chain. This does not change the fact that the affected bits may happen every the number of the addresses.

### Counter-Based Scan Chain Diagnosis Tool

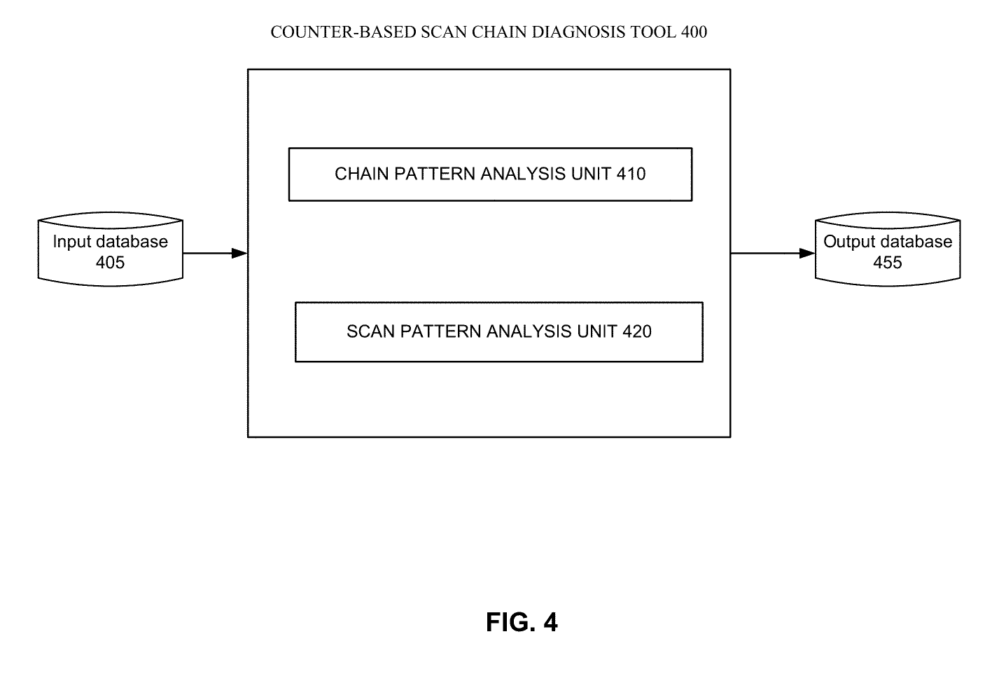

FIG. 4 illustrates an example of a counter-based scan chain diagnosis tool 400 that may be implemented according to various embodiments of the disclosed technology. As seen in this figure, the counter-based scan chain diagnosis tool 400 includes a chain pattern analysis unit 410 and a scan pattern analysis unit 420. Some implementations of the counter-based scan chain diagnosis tool 400 may cooperate with (or incorporate) one or more of an input database 405 and an output database 455.

As will be discussed in more detail below, the chain pattern analysis unit 410 analyzes chain pattern responses of a circuit generated by a first process. The chain pattern analysis unit 410 may receive the chain pattern responses from the input database 405. The first process comprises shifting in chain patterns and shifting out the chain pattern responses. The chain pattern response analysis determines at least one or more chain segment defect candidates on one faulty scan chain in the circuit and a fault model associated with the one faulty scan chain. Each of the one or more chain segment defect candidates is a counter-based scan chain unit derived from a part or a whole of a memory array. The information of the part or the whole of the memory array is used by chain pattern analysis unit 410 to determine the one or more chain segment defect candidates.

Based on the fault model and the information of the part or the whole of the memory array, the scan pattern analysis unit 420 analyzes scan pattern responses generated by a second process to determine one or more memory cell defect candidates in the one or more chain segment defect candidates. The scan pattern analysis unit 420 may receive the scan pattern responses from the input database 405. The second process comprises shifting in scan patterns, capturing the scan pattern responses, and shifting out the scan pattern responses.

As previously noted, various examples of the disclosed technology may be implemented by one or more computing systems, such as the computing system illustrated in FIGS. 1 and 2. Accordingly, one or both of the chain pattern analysis unit 410 and the scan pattern analysis unit 420 may be implemented by executing programming instructions on one or more processors in one or more computing systems, such as the computing system illustrated in FIGS. 1 and 2. Correspondingly, some other embodiments of the disclosed technology may be implemented by software instructions, stored on a non-transitory computer-readable medium, for instructing one or more programmable computers/computer systems to perform the functions of one or both of the chain pattern analysis unit 410 and the scan pattern analysis unit 420. As used herein, the term “non-transitory computer-readable medium” refers to computer-readable medium that are capable of storing data for future retrieval, and not propagating electro-magnetic waves. The non-transitory computer-readable medium may be, for example, a magnetic storage device, an optical storage device, or a solid state storage device.

It also should be appreciated that, while the chain pattern analysis unit 410 and the scan pattern analysis unit 420 are shown as separate units in FIG. 4, a single computer (or a single processor within a master computer) or a single computer system may be used to implement all of these units at different times, or components of these units at different times.

With various examples of the disclosed technology, the input database 405 and the output database 455 may be implemented using any suitable computer readable storage device. That is, either of the input database 405 and the output database 455 may be implemented using any combination of computer readable storage devices including, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable storage devices may also include magnetic cassettes, magnetic tapes, magnetic disks or other magnetic storage devices, holographic storage devices, or any other non-transitory storage medium that can be used to store desired information. While the input database 405 and the output database 455 are shown as separate units in FIG. 4, a single data storage medium may be used to implement some or all of these databases.

### Defective Memory Cell Identification Based On Chain Diagnosis

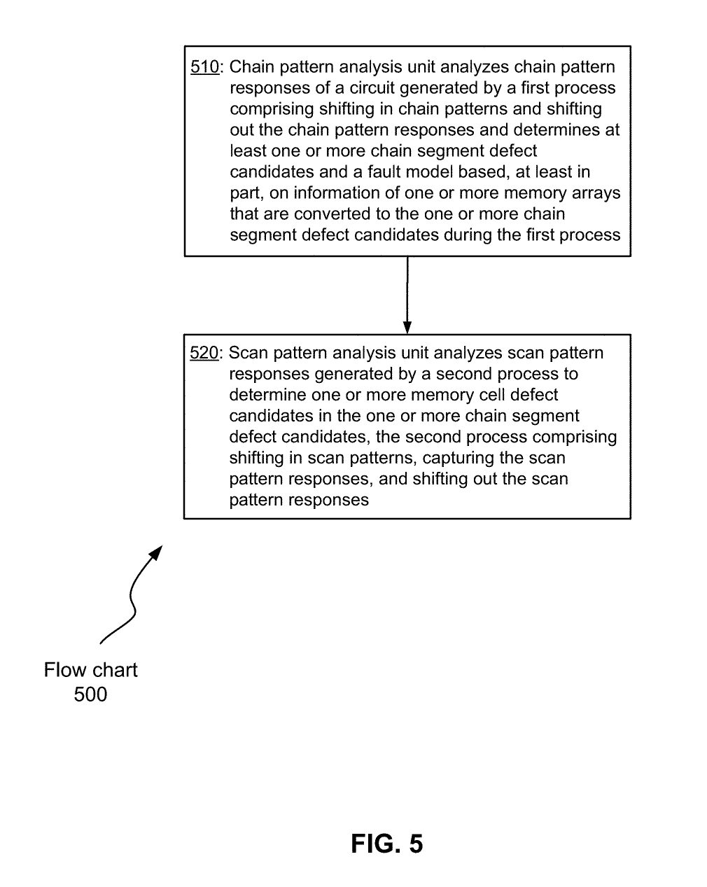

FIG. 5 illustrates a flowchart 500 showing a process of defective memory cell identification based on chain diagnosis that may be implemented according to various examples of the disclosed technology. For ease of understanding, methods of defective memory cell identification based on chain diagnosis that may be employed according to various embodiments of the disclosed technology will be described with reference to the counter-based scan chain diagnosis tool 400 in FIG. 4 and the flow chart 500 illustrated in FIG. 5. It should be appreciated, however, that alternate implementations of a counter-based scan chain diagnosis tool may be used to perform the methods of defective memory cell identification based on chain diagnosis illustrated by the flow chart 500 according to various embodiments of the disclosed technology. Likewise, the counter-based scan chain diagnosis tool 400 may be employed to perform other methods of defective memory cell identification based on chain diagnosis according to various embodiments of the disclosed technology.

In operation 410, the chain pattern analysis unit 410 analyzes chain pattern responses of a circuit generated by a first process. The chain pattern analysis unit 410 may receive the chain pattern responses from the input database 405. The first process comprises shifting in chain patterns and shifting out the chain pattern responses. The chain pattern response analysis determines at least one or more chain segment defect candidates on one faulty scan chain in the circuit and a fault model associated with the one faulty scan chain.

Normally, the patterns used in chain diagnosis can be classified into two categories: (1) A chain pattern is a pattern used in a process comprising shift-in and shift-out without pulsing capture clocks and may be used to test the integrity of scan chains and/or determine fault models associated with faulty scan chains; (2) a scan pattern is a pattern used in a process comprising shift-in, one or multiple capture clock cycles, and shift-out, and the scan patterns include ATPG (Automatic Test Pattern Generation) scan pattern generated for testing system logic, special chain diagnostic patterns generated only for scan chain diagnosis purpose and some special functional patterns. The first process may use conventional chain patterns to generate the chain pattern responses which are unloaded chain patterns.

The one faulty scan chain is a scan chain that fails at least one of the chain patterns—the unloaded chain pattern response is different from the one of the chain patterns. For a good scan chain, chain patterns will not change after being shifted into and out of the scan chain. Each of the one or more chain segment defect candidates is a chain segment of the one faulty scan chain that is a suspect for containing a defective scan cell. A chain segment is a counter-based scan chain unit derived from a part or a whole of a memory array. A scan chain can have zero, one or multiple such units along with conventional scan cells. A scan chain can also have only such unit(s) without normal scan cells.

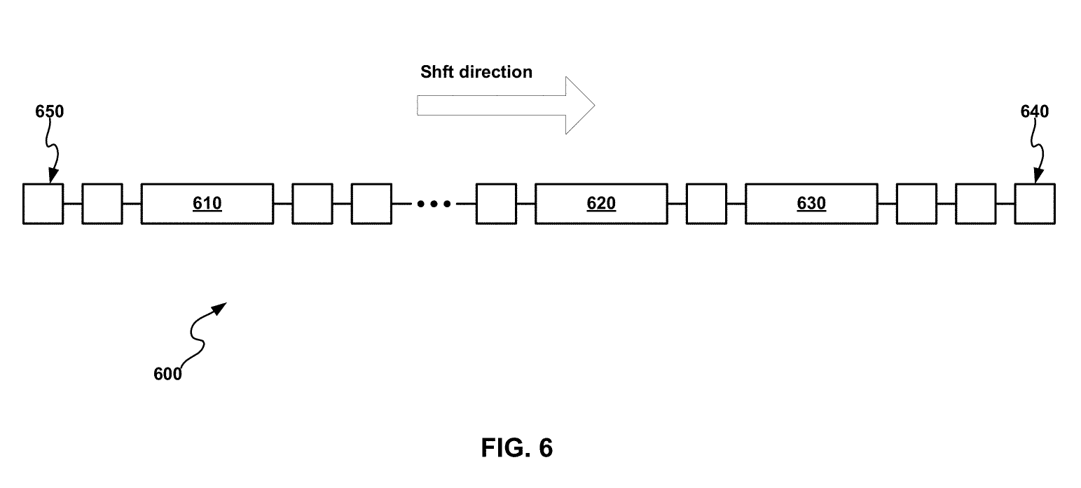

FIG. 6 illustrates an example of a scan chain having multiple counter-based scan chain units along with conventional scan cells. In the figure, conventional scan cells on scan chain 600 are illustrated by squares and three chain segments (counter-based scan chain units) 610, 620 and 630 are illustrated by rectangles. The three chain segments 610-630 may be derived from one, two or three memory arrays. For instance, the chain segment 610 is derived from all memory cells in a first memory array while each of the chain segments 620 and 630 are derived from one half of data bit cells of a second memory array.

To describe the diagnosis algorithms, typically each scan cell on a scan chain is given an index. Without losing generality, the cell connected to scan-output is numbered 0 and the cells in the chain are numbered incrementally from scan-output to scan-input. In FIG. 6, scan cell 640 has an index of 0 while scan cell 650 has an index of (n-1). Here, n represents the total number of scan cells on the scan chain 600. The scan cells between the scan chain input and the scan input terminal of a scan cell are called the “upstream cells” of the scan cell, while the scan cells between the scan chain output and the scan output terminal of a scan cell are called the “downstream cells” of the scan cell.

Typically, the analysis of chain pattern responses not only can identify faulty scan chains but also may determine the fault model associated with each of the faulty scan chains. With various implementations of the disclosed technology, the fault models for scan chains include stuck-at faults (stuck-at-0/stuck-at-1), slow faults (slow-to-rise/slow-to-fall/slow) and fast faults (fast-to-rise/fast-to-fall/fast). Slow faults are normally caused by setup-time violations while fast faults are normally caused by hold-time violations. The fault models often include a fault model reserved for those that can be assigned to none of the above fault models. With a specific fault model, a scan chain defect can also be modeled as a permanent fault (the fault happens for all shift cycles) or an intermittent fault (the fault only happens for a subset of shift cycles). Note that the defect itself is still permanent, but the fault model used to represent the defect is intermittent. An intermittent fault may be used to describe some characteristics for an un-modeled defect. For example, an intermittent stuck-at-0 fault refers to a defect that can cause some shift operations to fail as if a stuck-at-0 fault intermittently appears while which shift cycles may fail is not known.

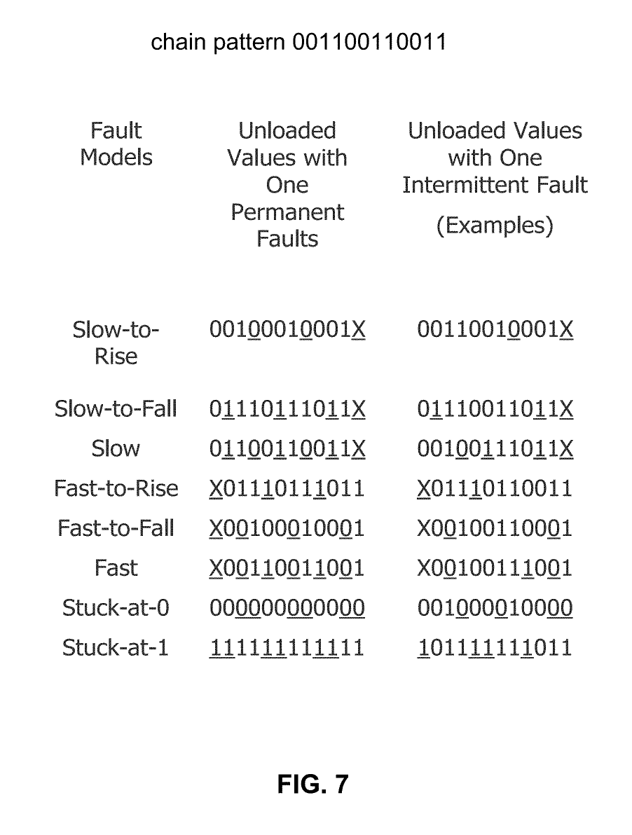

FIG. 7 illustrates an example of a chain pattern and chain pattern responses of a conventional faulty scan chain for the above eight fault models. The faulty scan chain has 12 scan cells and the chain pattern is 001100110011 where the leftmost bit is loaded into Cell 11 and the rightmost bit is loaded into Cell 0. The figure includes the chain responses (the unloaded faulty values) for each type of permanent faults examples of the chain responses (the unloaded faulty values) for each type of intermittent faults. A test pattern (chain pattern, scan pattern or special chain diagnostic pattern) may be considered as consisting of sensitive bits and insensitive bits. The sensitive bits are those whose values may be changed during scan chain shift operations. For different fault models, the sensitive bits are different. In FIG. 7, the sensitive bits for each fault model are indicated by underlines. By looking up this table shown in FIG. 7, one can identify the fault model associated with the faulty scan chain. FIG. 7 is just an example. Other types of fault models may also be included in the table.

If a counter-based scan chain unit contains a faulty scan cell, the chain pattern responses will be different from those for a conventional faulty scan chain. Suppose the faulty memory cell shown in FIG. 3C (the data bit cell #3 of address 1) has a stuck-at-0 fault. Unlike a conventional faulty scan chain, not any bit with a value of 1 is a sensitive bit. Rather, sensitive bits are limited to locations shown in FIG. 3D. Based on spacing between sensitive bit locations, the minimum spacing in particular, the chain pattern analysis unit 410 can determine the one or more chain segment defect candidates. These counter-based scan chain units usually have the same number of addresses. In some cases, these counter-based scan chain units may include one having the number of addresses multiple times the number of addresses for another one if an intermittent fault involved.

In the example shown in FIG. 6, suppose that the chain pattern responses show the minimum spacing between sensitive bits is four (e.g., one appears at bit location #2 and the other appears at bit location #6). If the counter-based scan chain units 610, 620 and 630 have four, five, and four memory addresses, respectively, the chain pattern analysis unit 410 may determine the counter-based scan chain units 610 and 630 as the chain segment defect candidates. On the other hand, if the counter-based scan chain units 610, 620 and 630 have four, eight, and four memory addresses, respectively and if an intermittent fault is determined, the chain pattern analysis unit 410 may determine all of the counter-based scan chain units 610, 620 and 630 as the chain segment defect candidates.

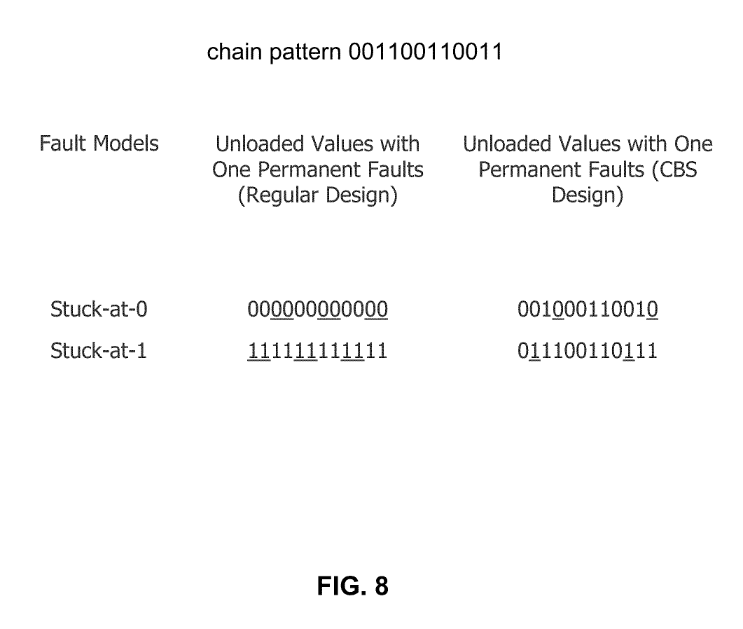

Tables like the one shown in FIG. 7 must be modified for it to be used by the chain pattern analysis unit 410 for the fault model determination if a counter-based scan chain unit is determined to be a chain segment defect candidate. FIG. 8 illustrates an example of fault model effect differences between conventional scan chains and scan chains containing a counter-based scan chain unit. The fault-free chain pattern response is “001100110011”. Effects of the stuck-at-1 and stuck-at-0 fault models are shown. The counter-based scan chain unit has eight memory addresses.

In operation 520 of the flowchart 500, the scan pattern analysis unit 420 analyzes scan pattern responses generated by a second process comprising shifting in scan patterns, capturing the scan pattern responses, and shifting out the scan pattern responses to determine one or more memory cell defect candidates in the one or more chain segment defect candidates based on the information of the part or the whole of the memory array and the fault model. The analysis performed by the scan pattern analysis unit 420 may comprise a model-based scan chain diagnosis process, a data-driven scan chain diagnosis result or both.

In a conventional model-based chain diagnosis process, a fault is algorithmically “injected” to one scan cell on a faulty chain. The loaded values of the downstream cells are accordingly modified for all scan patterns. For example, suppose a scan pattern has good machine loaded value 001110011010 on the faulty chain. If a permanent stuck-at-1 fault is injected on scan cell 8 of this chain, the loaded values will be modified as 001111111111. After pulsing the capture clock, the simulated captured values in the upstream of the faulty scan cell on this chain will also be modified. For example if the simulated captured value is 101011101011, the unloaded values will be 111111101011. The fault simulation is performed one cell at a time. The simulation results are compared with the results observed on ATE (Automated Test Equipment). The cell(s) that matches the best are reported as suspect(s).

A conventional faulty scan cell can cause all loading cycles downstream from the faulty cell to fail and cause all unloading cycles downstream from that cell to fail, if the value is opposite to the fault model value and the fault model is a permanent fault. For a scan chain include a faulty counter-based scan unit, a defect in the register file manifests as failing cycles that occur every n times in the loading/unloading operations, where n is the number of addresses of the faulty counter-based scan unit. Still using the prior example, if a permanent stuck-at-1 fault is injected on a memory cell and n is 4, the loaded values will be modified as, e.g., 001110011011. That is to say, only cycle 0 and cycle 4 have loading errors. After pulsing the capturing clock, the simulated captured values in the upstream of the faulty scan cell on this chain will be modified. For example if the simulated captured value is 101011101011, the unloaded values will be 101111101011. That is to say, only cycle 8 has an unloading error. Accordingly, the scan pattern analysis unit 420 modifies the loading and unloading values based on the information of the part or the whole of the memory array. The information comprises the number of addresses of the one or more chain segment defect candidates. The information may further comprise the locations for these counter-based scan chain units.

Different data-driven chain diagnosis methods can be employed by the scan pattern analysis unit 420. In one data-driven chain diagnosis process, special chain diagnosis patterns are used. These patterns could be either functional test patterns that start from an initial state, or scan patterns that start with all “0's or all “1's. The purpose of using such patterns is to avoid (or minimize) any faulty values introduced with the loading of scan chains. Therefore, all (or most) of the failing bits are caused in the process of unloading scan chains. Then the diagnosis can be performed by monitoring from which scan cell the signal probability has been significantly changed. These algorithms select patterns to randomize signal probability of scan cells before unloading. The failing scan cell position can be identified by comparing the observed signal profile on a tester and the expected signal profile.

In another data-driven chain diagnosis process, ATPG scan patterns are used. Potential loading-caused failures are filtered out by masking scan patterns based on the faulty scan chain information including the fault model. The masked scan patterns are then simulated to determine the failing probability information for each cell in a faulty scan chain. Based on the failing probability information, one or more defective cells in the faulty chain could be identified. An adaptive noise filtering system may be employed to help with the diagnosis process according to some embodiments of the invention. One example of the ATPG scan pattern-based data-driven chain diagnosis technique for conventional scan chain diagnosis is described in U.S. Pat. No. 8,689,070, entitled “Method and system for scan chain diagnosis,” naming Yu Huang et al. as inventors, which is incorporated herein by reference.

No matter which data-driven chain diagnosis process is performed, the scan pattern analysis unit 420 can determine the relationship between bits of the scan pattern responses and the scan cells including the data bit cells of the one or more memory cell defect candidates on the faulty scan chain based on the information of the part or the whole of the memory array. For the data-driven chain diagnosis process based on ATPG scan patterns, the scan pattern analysis unit 420 can also filter out potential loading-caused failure based on the fault type and the information of the part or the whole of the memory array.

In some embodiments of the disclosed technology, the scan pattern analysis unit 420 performs a data-driven chain diagnosis process to generate a data-driven scan chain diagnosis result and then performs a model-based scan chain diagnosis process to validate the data-driven scan chain diagnosis result.

The disclosed technology is applicable to circuits having test compress circuitry such as the Embedded Deterministic Test circuitry.

### Conclusion

Having illustrated and described the principles of the disclosed technology, it will be apparent to those skilled in the art that the disclosed embodiments can be modified in arrangement and detail without departing from such principles. In view of the many possible embodiments to which the principles of the disclosed technologies can be applied, it should be recognized that the illustrated embodiments are only preferred examples of the technologies and should not be taken as limiting the scope of the disclosed technology. Rather, the scope of the disclosed technology is defined by the following claims and their equivalents. We therefore claim as our disclosed technology all that comes within the scope and spirit of these claims.

What is claimed is:

1. A method, executed by at least one processor of a computer, comprising:
analyzing chain pattern responses of a circuit generated by a first process comprising shifting in chain patterns and shifting out the chain pattern responses, wherein the analyzing chain pattern responses determines at least one or more chain segment defect candidates on one faulty scan chain in the circuit and a fault model associated with the one faulty scan chain, and wherein each of the one or more chain segment defect candidates is a counter-based scan chain unit derived from a part or a whole of a memory array and the determining is based, at least in part, on information of the part or the whole of the memory array; and
analyzing scan pattern responses generated by a second process comprising shifting in scan patterns, capturing the scan pattern responses, and shifting out the scan pattern responses to determine one or more memory cell defect candidates in the one or more chain segment defect candidates based on the information of the part or the whole of the memory array and the fault model.

2. The method recited in claim 1, wherein the analyzing the scan pattern responses comprises performing a data-driven scan chain diagnosis process to generate a data-driven scan chain diagnosis result.

3. The method recited in claim 2, wherein the analyzing the scan pattern responses further comprises performing a model-based scan chain diagnosis process to validate the data-driven scan chain diagnosis result.

4. The method recited in claim 1, wherein the analyzing the scan pattern responses comprises performing a model-based scan chain diagnosis process.

5. The method recited in claim 1, wherein the fault model is a slow-rise fault, a slow-fall fault, a slow fault, a fast-rise fault, a fast-fall fault, a fast (hold time) fault, a stuck-at-1 fault, a stuck-at-0 fault, or an indeterminate fault.

6. The method recited in claim 1, wherein the information of the part or the whole of the memory array comprises a number of addresses of the memory array.

7. The method recited in claim 6, wherein the information of the part or the whole of the memory array further comprises location information of each of the one or more chain segment defect candidates.

8. The method recited in claim 1, wherein the scan patterns are ATPG scan patterns.

9. One or more non-transitory processor-readable media storing processor-executable instructions for causing one or more processors to perform a method, the method comprising:
analyzing chain pattern responses of a circuit generated by a first process comprising shifting in chain patterns and shifting out the chain pattern responses, wherein the analyzing chain pattern responses determines at least one or more chain segment defect candidates on one faulty scan chain in the circuit and a fault model associated with the one faulty scan chain, and wherein each of the one or more chain segment defect candidates is a counter-based scan chain unit derived from a part or a whole of a memory array and the determining is based, at least in part, on information of the part or the whole of the memory array; and
analyzing scan pattern responses generated by a second process comprising shifting in scan patterns, capturing the scan pattern responses, and shifting out the scan pattern responses to determine one or more memory cell defect candidates in the one or more chain segment defect candidates based on the information of the part or the whole of the memory array and the fault model.

10. The one or more non-transitory processor-readable media recited in claim 9, wherein the analyzing the scan pattern responses comprises performing a data-driven scan chain diagnosis process to generate a data-driven scan chain diagnosis result.

11. The one or more non-transitory processor-readable media recited in claim 10, wherein the analyzing the scan pattern responses further comprises performing a model-based scan chain diagnosis process to validate the data-driven scan chain diagnosis result.

12. The one or more non-transitory processor-readable media recited in claim 9, wherein the analyzing the scan pattern responses comprises performing a model-based scan chain diagnosis process.

13. The one or more non-transitory processor-readable media recited in claim 9, wherein the fault model is a slow-rise fault, a slow-fall fault, a slow fault, a fast-rise fault, a fast-fall fault, a fast (hold time) fault, a stuck-at-1 fault, a stuck-at-0 fault, or an indeterminate fault.

14. The one or more non-transitory processor-readable media recited in claim 9, wherein the information of the part or the whole of the memory array comprises a number of addresses of the memory array.

15. The one or more non-transitory processor-readable media recited in claim 14, wherein the information of the part or the whole of the memory array further comprises location information of each of the one or more chain segment defect candidates.

16. The one or more non-transitory processor-readable media recited in claim 9, wherein the scan patterns are ATPG scan patterns.

17. A system, comprising:
one or more processors, the one or more processors programmed to perform a method, the method comprising:
analyzing chain pattern responses of a circuit generated by a first process comprising shifting in chain patterns and shifting out the chain pattern responses, wherein the analyzing chain pattern responses determines at least one or more chain segment defect candidates on one faulty scan chain in the circuit and a fault model associated with the one faulty scan chain, and wherein each of the one or more chain segment defect candidates is a counter-based scan chain unit derived from a part or a whole of a memory array and the determining is based, at least in part, on information of the part or the whole of the memory array; and
analyzing scan pattern responses generated by a second process comprising shifting in scan patterns, capturing the scan pattern responses, and shifting out the scan pattern responses to determine one or more memory cell defect candidates in the one or more chain segment defect candidates based on the information of the part or the whole of the memory array and the fault model.

18. The system recited in claim 17, wherein the analyzing the scan pattern responses comprises performing a data-driven scan chain diagnosis process to generate a data-driven scan chain diagnosis result.

19. The system recited in claim 17, wherein the analyzing the scan pattern responses comprises performing a model-based scan chain diagnosis process.

20. The system recited in claim 17, wherein the information of the part or the whole of the memory array comprises a number of addresses of the memory array.
